(19) United States
(12) Patent Application Publication
(10) Pub. No.: US 2021/0050489 A1
(43) Pub. Date: Feb. 18, 2021

(54) PHOSPHOR SHEET, METHOD FOR THE PRODUCTION OF A PHOSPHOR SHEET, OPTOELECTRONIC DEVICE, METHOD FOR THE PRODUCTION OF AN OPTOELECTRONIC DEVICE

(71) Applicant: OSRAM Opto Semiconductors GmbH, Regensburg (DE)

(72) Inventors: Keng Chong LIM, Georgetown (MY); Norwin VON MALM, Nittendorf (DE)

(21) Appl. No.: 16/965,576

(22) PCT Filed: Mar. 12, 2018
(86) PCT No.: PCT/EP2018/056043

§ 371 Date: Jul. 28, 2020

(51) Int. Cl. H01L 33/50; H01L 33/46; C08J 5/12; C08J 7/04; C09K 11/02

(52) U.S. Cl. CPC H01L 33/504; H01L 33/46; C08J 5/124; C08J 7/0427; C08J 2483/04; H01L 2933/0025; H01L 2933/0041; C08J 2383/04; C09K 11/02

(57) ABSTRACT

A phosphor sheet (6) is provided comprising the following elements:
a first polymer sheet (1) of a first polymer material, which is partially cured,
a second polymer sheet (4) of a second polymer material, which is partially cured, and
a phosphor layer (4) comprising phosphor particles with a plurality of first phosphor particles, said first phosphor particles convert electromagnetic radiation of a first wavelength range into electromagnetic radiation of a second wavelength range,
   wherein
   the phosphor layer (3) is sandwiched between the first polymer sheet (1) and the second polymer sheet (4).

Further, a method for the production of a phosphor sheet (6), an optoelectronic device and a method for the production of an optoelectronic device are provided.

A phosphor sheet, a method for the production of a phosphor sheet, an optoelectronic device and a method for the production of an optoelectronic device are provided.

An improved phosphor sheet with a high phosphor content should be provided. In particular, the phosphor sheet should allow easy mounting on a radiation-emitting semiconductor chip. Further, an optoelectronic device with a phosphor sheet having a high phosphor content should be provided. Finally, a simplified method for the production of an optoelectronic device should be given.

These problems are solved by a phosphor sheet with the features of claim 1, by the method for the production of a phosphor sheet with steps of claim 11, by an optoelectronic device with the features of claim 13 and by a method for the production of an optoelectronic device with the steps of claim 18.

Advantageous embodiments of the phosphor sheet, of the method for the production of the phosphor sheet, of the optoelectronic device and of the method for the production of the optoelectronic device are given in the respective dependent claims.

According to an embodiment of the phosphor sheet, the phosphor sheet comprises a first polymer sheet of a first polymer material, which is partially cured.

According to a further embodiment of the phosphor sheet, the phosphor sheet comprises a second polymer sheet of a second polymer material, which is also partially cured. Particularly preferably, a surface of the first polymer sheet and/or the second polymer sheet is sticky.

The first polymer material and/or the second polymer material comprise a plurality of monomers. In a completely uncured state, the monomers are not connected to each other by chemical bonds. During polymerization, which can be initiated for example by UV-light or heat, monomers react chemically which each other to form chemical bonds. The term “partially cured” means that the monomers of the first polymer material and/or the monomers of the second polymer material are not completely polymerized. This leads particularly preferably to a sticky surface of the first polymer sheet and/or the second polymer sheet. If the polymerization of the first polymer material and/or the second polymer material further proceeds, a predominant part of the monomers are connected to each other by chemical bonds. This state of the first polymer material and/or the second polymer material is called a “completely cured state” in the following.

Particularly preferably, the phosphor sheet comprises a phosphor layer with a plurality of first phosphor particles. The first phosphor particles convert electromagnetic radiation of a first wavelength range into electromagnetic radiation of a second wavelength range, which is different from the first wavelength range. In other words, the phosphor particles of the phosphor layer are responsible for the wavelength converting properties of the phosphor sheet. For example, the plurality of first phosphor particles converts electromagnetic radiation of the blue spectral range into electromagnetic radiation of the yellow to green spectral range.

According to a further embodiment of the phosphor sheet, the phosphor layer is sandwiched between the first polymer sheet and the second polymer sheet. Preferably, the phosphor layer is at least along a main extension plane completely embedded within the first polymer sheet and the second polymer sheet. Particularly preferably, the phosphor layer is in direct contact with the first polymer sheet and/or the second polymer sheet.

The location of the phosphor layer sandwiched between the first polymer sheet and the second polymer sheet has the advantage that a heated spot within the first polymer sheet and/or the second polymer sheet can be reduced. This leads to a low heat degradation under long period application of the phosphor sheet.

According to a further embodiment of the phosphor sheet, the first polymer sheet and the second polymer sheet comprise the same polymer material. For example, the first polymer material and the second polymer material are equal to each other.

Particularly preferably, the first polymer material and/or the second polymer material comprise silicone. It is also possible that the first polymer material and/or the second polymer material consist of silicone.

According to a preferred embodiment of the phosphor sheet, the first polymer material and/or the second polymer material are at least in the completely cured state transparent to electromagnetic radiation at least of the first wavelength range and the second wavelength range. The term “transparent” means that the indicated element is at least transmissible for 85%, preferably for 90% and particularly preferably for 95% of electromagnetic radiation of the indicated wavelength range. According to a preferred embodiment of the phosphor sheet, the first polymer sheet and/or the second polymer sheet are free of phosphor particles.

According to a further embodiment of the phosphor sheet, the phosphor layer comprises a binder. For example, the binder is also a polymer material, preferably a silicone. For example, the binder equals the first polymer material and/or the second polymer material. The binder is intended to mechanically connect the phosphor particles with each other. Further, the binder is responsible for the mechanical stability of the phosphor layer at least in a cured state. Further, the binder provides a mechanically stable connection of the phosphor layer to the first polymer sheet and to the second polymer sheet, also at least in a cured state.

Alternatively, it is also possible that the phosphor layer is only formed of phosphor particles. Such a phosphor powder layer preferably has a very low thickness. Particularly preferably, the phosphor powder layer is a monolayer of phosphor particles and the thickness of the phosphor powder layer is determined by a diameter of the phosphor particles. The diameter of the phosphor particles lies for example between 10 micrometer and 30 micrometer, limits included.

According to a further embodiment of the phosphor sheet, the first polymer sheet comprises a radiation entrance surface of the phosphor sheet and the second polymer sheet comprises a radiation exit surface of the phosphor sheet. The radiation entrance surface of the phosphor sheet and the radiation exit surface of the phosphor sheet each preferably forms an outer surface of the phosphor sheet. The radiation entrance surface of the phosphor sheet and the radiation exit surface of the phosphor sheet are arranged opposite to each other.

Particularly preferably, the radiation entrance surface and/or the radiation exit surface of the phosphor sheet is particularly preferably free of phosphor particles. Further, the radiation entrance surface and/or the radiation exit surface of the phosphor sheet is particularly preferably sticky.

According to a further embodiment of the phosphor sheet, the first polymer sheet has a refractive index, which is smaller than the refractive index of the second polymer sheet. For example, the refractive index of the first polymer sheet lies between 1,1 and 1,3 and/or the refractive index of the second polymer sheet lies between 1,4 and 1,5, limits included respectively.

According to a further embodiment of the phosphor sheet, the phosphor particles comprise a plurality of second phosphor particles. The second phosphor particles convert electromagnetic radiation of the first wavelength range in electromagnetic radiation of a third wavelength range, different from the first wavelength range and the second wavelength range. For example, the plurality of second phosphor particles convert electromagnetic radiation of the blue spectral range into electromagnetic radiation of the red spectral range.

For example, one of the following materials is suitable for the plurality of first phosphor particles and/or for the plurality of second phosphor particles: garnets doped with rare earths, sulfides doped with rare earths, thiogallates doped with rare earths, aluminates doped with rare earths, silicates doped with rare earths, orthosilicates doped with rare earths, nitrides doped with rare earths, oxinitrides doped with rare earths, chlorosilicates doped with rare earths, silicon nitrides doped with rare earths, sialones doped with rare earths.

According to a further embodiment of the phosphor sheet, the first polymer sheet and/or the second polymer sheet have a thickness between 5 micrometer and 10 micrometer, limits included. According to a further embodiment of the phosphor sheet, the phosphor layer has a thickness between 30 micrometer and 40 micrometer, limits included. The total thickness of the phosphor sheet lies preferably between 35 micrometer and 50 micrometer.

The phosphor sheet described above can be manufactured by the method described in the following. Embodiments, features and elements described in connection with the phosphor sheet can also be realized in connection with the method and vice versa.

According to an embodiment of the method for the production of a phosphor sheet, a first polymer sheet is provided. The first polymer sheet preferably comprises a first polymer material, which is partially cured.

According to a further embodiment of the method, a phosphor layer is applied to the first polymer sheet. Preferably, the phosphor layer comprises a plurality of first phosphor particles converting electromagnetic radiation of a first wavelength range in electromagnetic radiation of a second wavelength range different from the first wavelength range.

In a further embodiment of the method, a second polymer sheet of a second polymer material is laminated to the first polymer sheet such that the phosphor layer is sandwiched between the first polymer sheet and the second polymer sheet. Also, the second polymer material of the second polymer sheet is particularly preferably only partially cured.

For example, a first polymer sheet and/or a second polymer sheet are manufactured by one of the following methods: tape casting, spin coating, doctor blading. During each of these methods the first polymer material and/or the second polymer material are generated in a sheet-like form in a liquid state and then partially cured, for example by heat or UV-light. Particularly preferably, the first polymer sheet and/or the second polymer sheet are cured to such an extent that the first polymer sheet and/or the second polymer sheet forms a continuous and mechanically stable layer. Before curing the first polymer material and/or the second polymer material these are in a liquid state. During the curing process the first polymer material and/or the second polymer material change their state from liquid to solid due to the polymerization process.

According to a particularly preferable embodiment of the phosphor sheet, the surfaces of the first polymer sheet and/or the second polymer sheet are sticky, since the first polymer material and/or a second polymer material are only partially cured.

According to a preferred embodiment of the method, the step of applying a phosphor layer comprises that the phosphor particles are introduced into a binder. Particularly preferably, the binder is in a liquid uncured state when the phosphor particles are introduced. For example, the binder can be a polymer material such as a silicone. The binder with the phosphor particles is for example spray-coated onto the first polymer sheet. After the deposition of the binder/phosphor particle mixture to the first polymer sheet, the binder is cured at least partially according to an embodiment of the method. During the curing of the binder, a continuous and mechanically stable phosphor layer is formed particularly preferably.

According to an alternative embodiment of the method, the step of applying a phosphor layer comprises that the phosphor particles are deposited onto the first polymer sheet by electrostatic forces, for example by electrostatic spraying. In particular, a phosphor powder layer, which is free of a binder, can be applied by electrostatic spraying using electrostatic forces.

The phosphor sheet described herein is in particular suitable for the use in an optoelectronic device. Features, elements and embodiments, which are described in connection with the phosphor sheet, can be also embodied within the optoelectronic device and vice versa.

According to an embodiment of the optoelectronic device, the optoelectronic device comprises a semiconductor chip emitting electromagnetic radiation of a first wavelength range from a radiation exit surface.

For example, the semiconductor chip is a flip-chip. A flip-chip comprises a carrier and a semiconductor layer sequence with a radiation generating active zone, wherein the semiconductor layer sequence is epitaxially grown on a main extension plane of the carrier. The carrier is particularly preferably transparent at least for the electromagnetic radiation of the active zone. For example, the carrier comprises or consists of one of the following materials: sapphire, silicon carbide. The carrier comprises a second main extension plane opposite to the first extension plane, the second main extension plane comprising preferably a radiation exit surface of the flip-chip at least partially. Also, side faces of the carrier form a part of the radiation exit surface, preferably. In other words, electromagnetic radiation generated within the active zone is preferably emitted via the second main extension plane and the side surfaces of the carrier. The second main extension plane of the carrier shows to a front side of the flip-chip or forms a front side of the flip-chip. A backside of the flip-chip arranged opposite to front side comprises preferably at least two electric contacts, while the front side of the flip-chip is preferably free of electrical contacts.

Preferably, the epitaxial layer sequence and in particular its active zone is based on a nitride compound semiconductor material or is formed from a nitride compound semiconductor material. Nitride compound semiconductor materials are compound semiconductor materials which comprises nitrogen such as the materials of the system InₓAl_{y}Ga_{1-x-y}N, wherein 0≤x≤1, 0≤y≤1 and x+y≤1. Epitaxial layer sequences based on a nitride compound semiconductor material are suitable to generate blue light in general.

The epitaxial layer sequence based on a nitride compound semiconductor material can for example be epitaxially grown on a carrier comprising sapphire or silicon carbide or consisting of one of these materials. Further, sapphire and silicon carbide are transparent for electromagnetic radiation of the blue spectral range as it can be generated by the epitaxial layer sequence based on a nitride compound semiconductor material in general.

Particularly preferably, a phosphor sheet is arranged on the radiation exit surface of the semiconductor chip. The phosphor sheet is suitable to convert electromagnetic radiation emitted by the semiconductor chip, for example blue light, at least partially into electromagnetic radiation of one or more wavelength ranges, which are different from the electromagnetic radiation emitted by the semiconductor chip. For example, the phosphor sheet converts blue light of the semiconductor chip in yellow, yellow to green and/or red light.

Preferably, the first polymer sheet and/or the second polymer sheet are thin enough that the phosphor layer is positioned close enough to the semiconductor chip for effective heat dissipation. As already outlined above, a suitable thickness of the first polymer sheet and/or the second polymer sheet lies for example between 5 micrometer and 10 micrometer, limits included.

According to a further embodiment of the optoelectronic device, the phosphor sheet comprises a first polymer sheet, a second polymer sheet and a phosphor layer sandwiched between the first polymer sheet and the second polymer sheet. The first polymer sheet and the second polymer sheet are particularly preferably completely cured within the finished optoelectronic device.

According to a further embodiment of the optoelectronic device, the phosphor layer comprises phosphor particles with a plurality of first phosphor particles converting electromagnetic radiation of the first wavelength range at least partially into electromagnetic radiation of the second wavelength range.

Particularly preferably, the phosphor sheet is in direct contact with the radiation exit surface of the semiconductor chip. Particularly preferably, a radiation entrance surface of the phosphor sheet is in direct contact with the radiation exit surface of the semiconductor chip. Particularly preferably, the optoelectronic device is free of an additional adhesion layer fixing the phosphor sheet to the semiconductor chip.

According to a further embodiment of the optoelectronic device, the phosphor sheet comprises a plurality of second phosphor particles converting electromagnetic radiation of the first wavelength range at least partially in electromagnetic radiation of a third wavelength range.

Particularly preferably, the first wavelength range comprises blue light, the second wavelength range comprises green to yellow light and the third wavelength range comprises red light. According to this embodiment of the optoelectronic device, the optoelectronic device emits mixed light of the first wavelength range, the second wavelength range and the third wavelength range. The mixed light particularly preferably is warm white. The colour temperature of the warm white mixed light lies for example between 2300 K and 3300 K, limits included.

A phosphor sheet suitable for the generation of warm white light in connection with a blue light emitting semiconductor chip comprises as a rule a quite thick phosphor layer with several layers of phosphor particles. In order to provide mechanical stability of a phosphor sheet with such a phosphor layer, the phosphor layer comprises particularly preferably a binder. In other words a phosphor sheet suitable for the production of warm white light preferably comprises a phosphor layer with a binder.

According to a further embodiment of the optoelectronic device, the mixed light is neutral to cold white. The colour temperature of the neutral to cold white mixed light lies for example between 3300 K and 5300 K, limits included. In this case, a phosphor sheet can be used, wherein the phosphor layer is a powder phosphor layer, which is only formed by phosphor particles. In other words a phosphor sheet suitable for the production of cold white to neutral white light preferably comprises a phosphor layer free of a binder. Preferably, the phosphor particles comprise according to this embodiment only a first plurality of phosphor particles converting for example blue light in yellow to green light. Further, the phosphor powder layer is formed preferably from a monolayer of phosphor particles.

According to a further embodiment of the optoelectronic device, the semiconductor chip is laterally embedded in a reflective coating. For example, the reflective coating comprises a silicone material with reflective particles, for example titan dioxide particles. Preferably, the reflective coating is flush with the radiation exit surface of the semiconductor chip. Particularly preferably, the radiation exit surface of the semiconductor chip is free of the reflective coating. Particularly preferably, the optoelectronic device is free of a further housing. Instead, the reflective coating stabilizes the optoelectronic device mechanically.

According to a further embodiment of the optoelectronic device, the phosphor sheet covers a main surface of the optoelectronic device comprising a surface of the reflective coating and the radiation exit surface of the semiconductor chip completely.

According to a further embodiment of the optoelectronic device, the first polymer sheet has a refractive index, which is smaller than the refractive index of the second polymer sheet. If the first polymer sheet has a smaller refractive index than the second polymer sheet, the out-coupling of electromagnetic radiation from the optoelectronic device can be optimized.

The optoelectronic device can for example be produced by the method described in the following. Embodiments, features and elements described in connection with the optoelectronic device can also be realized in connection with the method and vice versa.

According to an embodiment of a method for the production of a plurality of optoelectronic devices, a phosphor sheet described herein is provided. The phosphor sheet comprises a first polymer sheet with a first polymer material partially cured. Further, the phosphor sheet comprises a second polymer sheet with a second polymer material also only partially cured. The phosphor sheet has particularly preferably a sticky radiation entrance surface.

According to a further embodiment of the method, a plurality of radiation-emitting semiconductor chips is positioned on a radiation entrance surface of the phosphor sheet at a distance to each other.

Particularly preferably, the radiation-emitting semiconductor chips are pressed to the radiation entrance surface of the phosphor sheet during or after the positioning step. Since the phosphor sheet has particularly preferably a sticky radiation entrance surface, the semiconductor chips adhere to the phosphor sheet by pressing without the use of an additional adhesive layer.

According to a further embodiment of the method, regions between the semiconductor chips are filled with a reflective coating. Particularly preferably, the reflective coating is in a liquid state during this method step. For example, the reflective coating is a silicone with reflective particles such as titan dioxide particles.

According to a further embodiment of the method, the first polymer material and/or the second polymer material and/or the reflective coating are cured completely. The curing of these materials can be conducted in a common step or in separate steps.

Finally, the generated compound comprising the semiconductor chips, the phosphor sheet and the reflective coating is separated in a plurality of optoelectronic devices. Preferably, the separation takes place by sawing or cutting through the cured reflective coating.

The present phosphor sheet has the advantage that a high content of phosphor particles can be incorporated within the phosphor sheet while obtaining a sticky surface for easy mounting of the phosphor sheet for example to a semiconductor chip. Compared to a common phosphor sheet, wherein the phosphor particles are distributed homogenously within the whole phosphor sheet, the surface of the present phosphor sheet can be embodied sticky, while the surface of the common phosphor sheet is non-sticky due to the high phosphor content.

Further preferred embodiments and developments of the phosphor sheet, the method for the production of the phosphor sheet, the optoelectronic device and the method for the production of the optoelectronic device are described in the following in connection with the Figures.

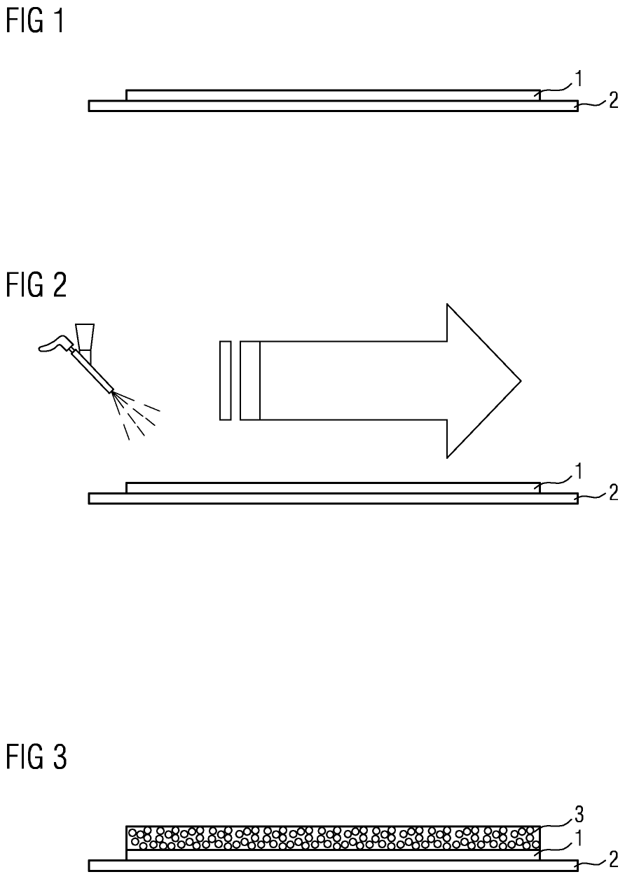

In connection with the schematic sectional views of FIGS. 1 to 4, a method for the production of a phosphor sheet according to an exemplary embodiment is explained in further detail.

FIG. 5 shows a schematic sectional view of a phosphor sheet according to an exemplary embodiment.

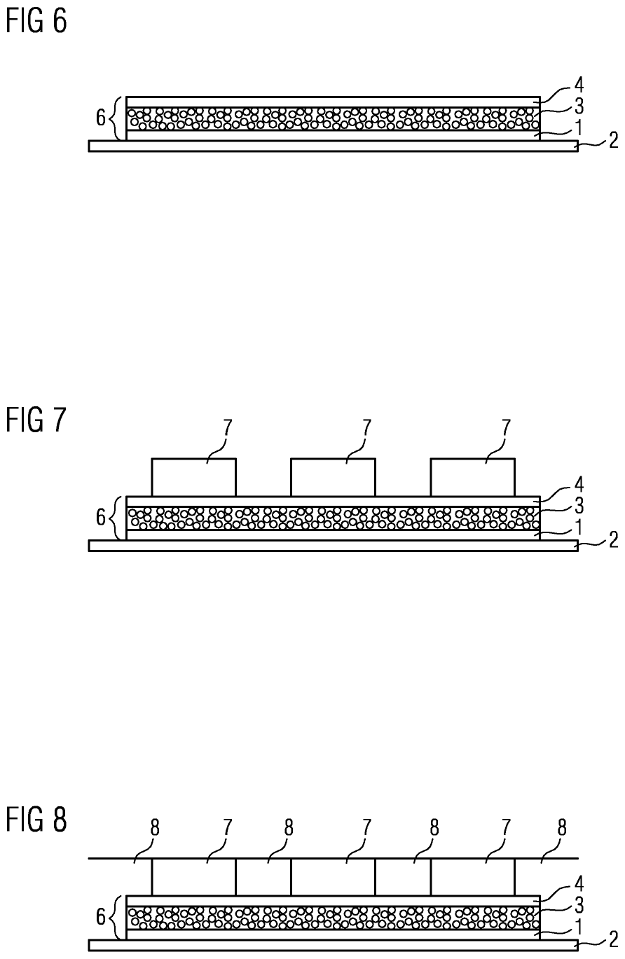

In connection with the schematic sectional views of FIGS. 6 to 9, a method for the production of an optoelectronic device according to an exemplary embodiment is explained in further detail.

FIG. 10 shows a schematic sectional view of an optoelectronic device according to an exemplary embodiment.

Equal or similar elements as well as elements of equal function are designated with the same reference signs in the figures. The figures and the proportions of the elements shown in the figures are not regarded as being shown to scale. Rather, single elements, in particular layers, can be shown exaggerated in magnitude for the sake of better presentation.

According to the method of the exemplary embodiment of FIGS. 1 to 4, a first polymer sheet 1 of a first polymer material is provided on a protective foil 2 to enable easy handling (FIG. 1). The first polymer sheet 1 of the first polymer material is just partially cured such that the surface of the first polymer sheet 1 is sticky. The first polymer sheet 1 is provided on the protective foil 2 in order to allow easy handing of the first polymer sheet 1 in spite of the sticky surface. The first polymer sheet 1 is particularly preferably manufactured from a silicone material, which is transparent for electromagnetic radiation of the visible spectral range.

In a next step, a phosphor layer 3 is deposited on the first polymer sheet 1 (FIG. 2). For the deposition of the phosphor layer 3 on the first polymer sheet 1, a plurality of first phosphor particles in introduced in a binder. The plurality of first phosphor particles converts electromagnetic radiation of a first wavelength range into electromagnetic of a second wavelength range. The mixture of the binder and the phosphor particles is deposited on the first polymer sheet 1 by spray coating. After the deposition of the phosphor layer 3 by spray coating, the binder is particularly preferably at least partially cured (FIG. 3).

It is also possible that a phosphor powder layer 3 is deposited on the first polymer sheet 1, for example by electrostatic spraying. The phosphor powder layer 3 is formed from phosphor particles and free of a binder material.

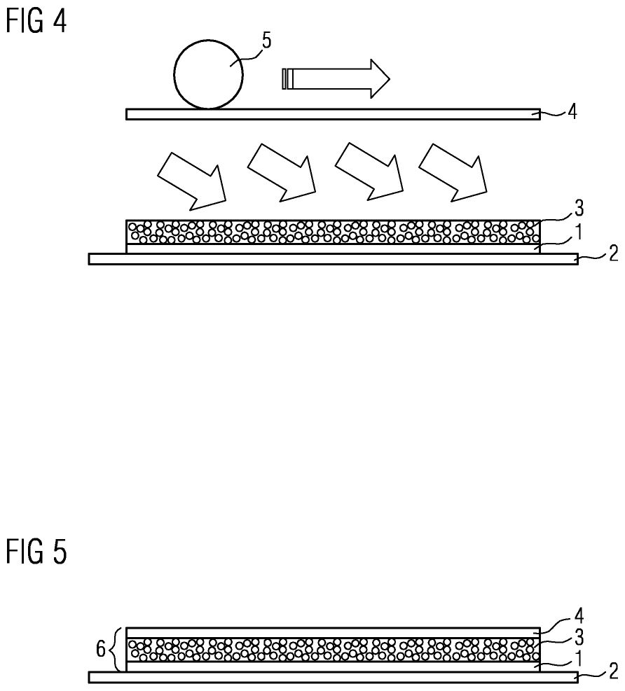

In a next step shown schematically in FIG. 4, a second polymer sheet 4 of a second polymer material is laminated to the phosphor layer 3, for example with the help of a roller 5. Also, the second polymer sheet 4 comprises a second polymer material, which is partially cured.

The phosphor sheet 6 according to the exemplary embodiment of FIG. 5 can, for example, be manufactured with the method explained in connection with FIGS. 1 to 4. The phosphor sheet 6 is deposited on a protective foil 2 according to the exemplarily embodiment of FIG. 5.

The phosphor sheet 6 according to the exemplary embodiment of FIG. 5 comprises a first polymer sheet 1 of a first polymer material, which is partially cured and a second polymer sheet 4 of a second polymer material, which is also partially cured. The first polymer sheet 1 and the second polymer sheet 4 preferably comprise a silicone. The surfaces of the first polymer sheet 1 and the second polymer sheet 4 are sticky, since the polymer materials of the first polymer sheet 1 and the second polymer sheet 4 are only partially cured.

Further, the phosphor sheet 6 comprises a phosphor layer 3 with phosphor particles. For example, the phosphor particles comprise a plurality of first phosphor particles, which convert electromagnetic radiation of the first wavelength range into electromagnetic radiation of a second wavelength range. Preferably, the phosphor particles comprise a plurality of second phosphor particles, which convert electromagnetic radiation of the first wavelength range into electromagnetic radiation of the third wavelength range. Particularly preferably, the first plurality of phosphor particles convert blue light into yellow to green light and the second plurality of phosphor particles convert blue light into red light.

The phosphor layer 3 is sandwiched between the first polymer sheet 1 and the second polymer sheet 4. The phosphor layer 3 is particularly preferably in direct contact with the first polymer sheet 1 and with the second polymer sheet 4.

During the method for the production of a plurality of optoelectronic devices according to the exemplary embodiment of FIGS. 6 to 9, a phosphor sheet 6 is provided on a protective foil 2 in a first step (FIG. 6). For example, the phosphor sheet 6 of the exemplary embedment of FIG. 5 can be used.

In a next step, schematically shown in FIG. 7, a plurality of semiconductor chips 7 is positioned on a radiation entrance surface of the phosphor sheet 6. The semiconductor chips 7 emit electromagnetic radiation, such as blue light, from a radiation exit surface. The semiconductor chips are positioned at a distance to each other. The semiconductor chips 7 are preferably flip-chips. The semiconductor chips 7 are applied to the phosphor sheet 6 with the main extension plane comprising at least a part of the radiation exit surface of the semiconductor chips 7.

In the next step, schematically shown in FIG. 8, the regions between the semiconductor chips 7 are filled with a reflective coating 8, for example by doctor blading, casting or jetting. The reflective coating 8 is, for example, formed by a silicone material with reflective particles such as titan dioxide particles. The reflective coating 8 forms a surface which is preferably flush with the main extension plane comprising at least partially the radiation exit surface of the semiconductor chips 7.

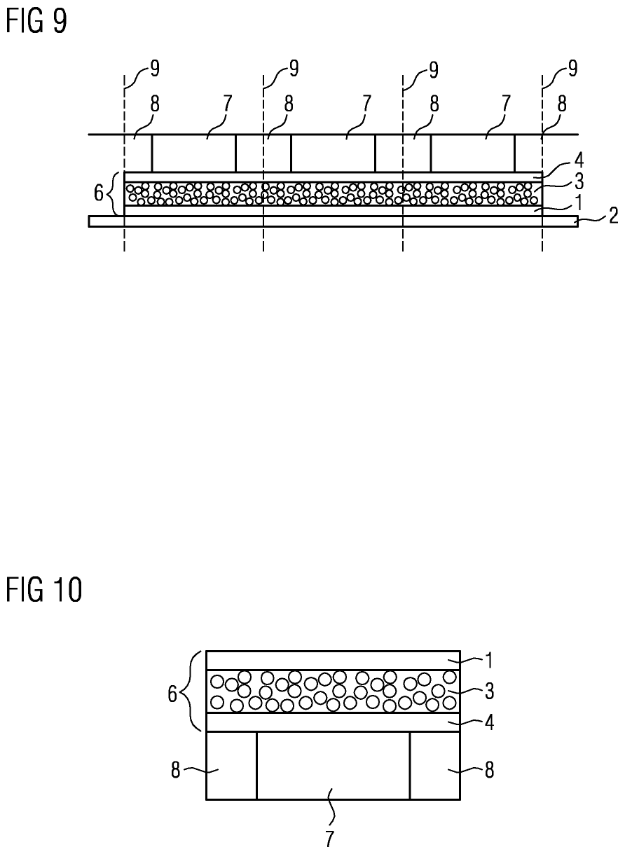

Then, the first polymer material of the first polymer sheet 1 and/or the second polymer material of the second polymer sheet 4 and/or the reflective coating 8 are cured. Particularly preferably, the first polymer material of the first polymer sheet 1 and/or the second polymer material of the second polymer sheet 4 and/or the reflective coating 8 are cured completely. Then, the generated compound of phosphor sheet 6, semiconductor chips 7 and reflective coating 8 is separated in a plurality of optoelectronic devices along separation lines 9 (FIG. 9).

The optoelectronic device according to the exemplary embodiment of FIG. 10 comprises a semiconductor chip 7 with a radiation exit surface. The radiation exit surface is at least partially in direct contact with the phosphor sheet 6. The phosphor sheet 6 is, for example, described in further detail in connection with FIG. 5. The phosphor sheet 6 converts electromagnetic radiation emitted by the radiation-emitting semiconductor chip 7, for example blue light, partially in red light and partially in yellow to green light such that the optoelectronic device emits mixed radiation consisting of blue light, red light and yellow to green light. The mixed light has a colour temperature in the warm white region. Laterally, the semiconductor chip 7 is surrounded by a reflective coating 8, for example by a silicone, which is filled with reflective titan dioxide particles. The reflective coating 8 reflects electromagnetic radiation, which is emitted via side faces of the semiconductor chip 7 such that the efficiency of the optoelectronic device is enhanced.

The invention is not limited to the description of the embodiments. Rather, the invention comprises each new feature as well as each combination of features, particularly each combination of features of the claims, even if the feature or the combination of features itself is not explicitly given in the claims or embodiments.

### REFERENCE SIGNS

1 first polymer sheet
2 protective foil
3 phosphor layer
4 second polymer sheet
5 roller
6 phosphor sheet
7 semiconductor chip
8 reflective coating
9 separation line

1. Phosphor sheet comprising:
a first polymer sheet of a first polymer material, which is partially cured,
a second polymer sheet of a second polymer material, which is partially cured, and
a phosphor layer comprising phosphor particles with a plurality of first phosphor particles, said first phosphor particles convert electromagnetic radiation of a first wavelength range into electromagnetic radiation of a second wavelength range,
Wherein
the phosphor layer is sandwiched between the first polymer sheet and the second polymer sheet,
the first polymer sheet has a refractive index smaller than the refractive index of the second polymer sheet.

2. Phosphor sheet according to claim 1, wherein the first polymer material and/or the second polymer material are at least in a completely cured state transparent to electromagnetic radiation at least of the first wavelength range and the second wavelength range.

3. Phosphor sheet according to claim 1, wherein
the first polymer material and/or the second polymer material comprises silicone.

4. Phosphor sheet according to claim 1, wherein
the first polymer sheet and/or the second polymer sheet are free of a phosphor particles.

5. Phosphor sheet according to claim 1, wherein the phosphor layer comprises a binder.

6. Phosphor sheet according to claim 1, wherein
the first polymer sheet comprises a radiation entrance surface of the phosphor sheet,
the second polymer sheet comprises a radiation exit surface of the phosphor sheet.

7. Phosphor sheet according to claim 1, wherein the refractive index of the first polymer sheet lies between 1,1 and 1,3, limits included and/or the refractive index of the second polymer sheet lies between 1,4 and 1,5, limits included.

8. Phosphor sheet according to claim 1, wherein the phosphor particles comprises a plurality of second phosphor particles, which convert electromagnetic radiation of the first wavelength range in electromagnetic radiation of a third wavelength range.

9. Phosphor sheet according to claim 1, wherein the first polymer sheet and/or the second polymer sheet have a thickness between 5 micrometer and 10 micrometer, limits included.

10. Phosphor sheet according to claim 1, wherein the phosphor layer has a thickness between 30 micrometer and 40 micrometer, limits included.

11. Method for the production of a phosphor sheet with the following steps:
providing a first polymer sheet of a first polymer material, which is partially cured,
applying a phosphor layer to the first polymer sheet, said phosphor layer comprising phosphor particles with a plurality of first phosphor particles converting electromagnetic radiation of the first wavelength range in electromagnetic radiation of a second wavelength range,
laminating a second polymer sheet of a second polymer material, which is partially cured, to the first polymer sheet, such that the phosphor layer is sandwiched between the first polymer sheet and the second polymer sheet, wherein
the first polymer sheet has a refractive index smaller than the refractive index of the second polymer sheet.

12. Method according to claim 11, wherein step of applying the phosphor layer comprises:
introducing the phosphor particles into a binder,
spray-coating of the binder with the phosphor particles.

13. Optoelectronic device comprising:
a semiconductor chip emitting electromagnetic radiation of a first wavelength range from a radiation exit surface, and
a phosphor sheet arranged on the radiation exit surface of the semiconductor chip,
said phosphor sheet comprising a first polymer sheet, a second polymer sheet and a phosphor layer sandwiched between the first polymer sheet and the second polymer sheet,
said phosphor layer comprising a plurality of first phosphor particles converting electromagnetic radiation of the first wavelength range at least partially into electromagnetic radiation of a second wavelength range
wherein
the first polymer sheet has a refractive index smaller than the refractive index of the second polymer sheet.

14. Optoelectronic device according to claim 13, wherein a radiation entrance surface of the phosphor sheet is in direct contact with the radiation exit surface of the semiconductor chip.

15. Optoelectronic device according to claim 13, wherein the phosphor sheet comprises a plurality of second phosphor particles converting electromagnetic radiation of the first wavelength range in electromagnetic radiation of a third wavelength range.

16. Optoelectronic device according to claim 13, wherein
the first wavelength range comprises blue light,
the second wavelength range comprises green to yellow light,
the third wavelength range comprises red light, and
the optoelectronic device emits mixed light of the first wavelength range, the second wavelength range and the third wavelength range, the mixed light being warm white.

17. Optoelectronic device according to claim 13, wherein the semiconductor chip is laterally embedded in a reflective coating.

18. Method for the production of a plurality of optoelectronic devices comprising the following steps:
providing a phosphor sheet according to claim 1,
positioning a plurality of radiation emitting semiconductor chips on a radiation entrance surface of the phosphor sheet at a distance to each other,
filling regions between the semiconductor chips with a reflective coating,
curing the first polymer material and/or the second polymer material and/or the reflective coating, and
separating the generated compound in a plurality of optoelectronic devices.

19. Optoelectronic device according to claim 17, wherein
the reflective coating comprises a silicone material with reflective particles.
